(19) United States
(12) Patent Application Publication
(10) Pub. No.: US 2013/0300398 A1
(43) Pub. Date: Nov. 14, 2013

(54) DISCHARGE TEST CIRCUIT FOR TESTING WHETHER THERE IS CURRENT ON A CIRCUIT BOARD

(71) Applicants: HONG FU JIN PRECISION INDUSTRY (WUHAN) CO., LTD., (US); HON HAI PRECISION INDUSTRY CO., LTD., New Taipei (TW)

(72) Inventor: ZHONG-GANG WU, Wuhan (CN)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 13/794,804

(22) Filed: Mar. 12, 2013

(30) Foreign Application Priority Data
May 11, 2012 (CN) 201210145454.9

(51) Int. Cl. G01R 19/00

(52) U.S. Cl. CPC G01R 19/00
USPC 324/72

(57) ABSTRACT

An exemplary discharge test circuit for testing whether there is current on a circuit board includes a comparison module, a switch module, a control module and a display module. The comparison module receives a first direct current (DC) voltage from the circuit board, compares the first DC voltage with a reference voltage, and outputs a switch signal according to a result of the comparison. The switch module receives the switch signal, and output a control signal accordingly. The control module receives the control signal, determines a status of the circuit board according to the control signal, and outputs a display signal corresponding to the status of the circuit board. The display module receives the display signal, and displays whether there is current on the circuit board according to the display signal.

### BACKGROUND

1. Technical Field

The present disclosure relates to a test circuit for testing whether a circuit board such as a motherboard has completed discharging during a power on test of the circuit board.

2. Description of Related Art

In computer systems such as a personal computer (PC) system, a power on test for a motherboard of the PC system is an important test in determining the reliability of the PC system. A typical power on test is performed by an operator, who presses a power button of the PC system to ground a sixth terminal of a computer front panel header, thereby turning on the computer system and keeping the system running for a long period of time to analyze the reliability of the motherboard. After the period of time has expired, the operator turns off the computer system, and then turns on the computer system once more to again keep the system running for a long period of time to analyze the reliability of the motherboard. These cycles of analyzing the reliability of the motherboard are repeated a desired number of times according to a testing protocol. It is common for the protocol to require as many as a thousand cycles, wherein it is necessary to power up the motherboard a thousand times. However, the above-described testing method cannot detect whether the motherboard has completely discharged after the computer system has been turned off. If the motherboard has not completely discharged before the computer system is turned on again for the next cycle, this may cause error in the next cycle.

Therefore there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an embodiment of a discharge test circuit and a motherboard under test, wherein the discharge test circuit includes a comparison module, a switch module, a control module, a display module, a power on module, and an indication module.

FIG. 2 is a circuit diagram of the comparison module, the switch module, the power on module, the indication module, and the motherboard of FIG. 1.

FIG. 3 is a circuit diagram of the control module and the display module of FIG. 1.

### DETAILED DESCRIPTION

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references can mean “at least one.”

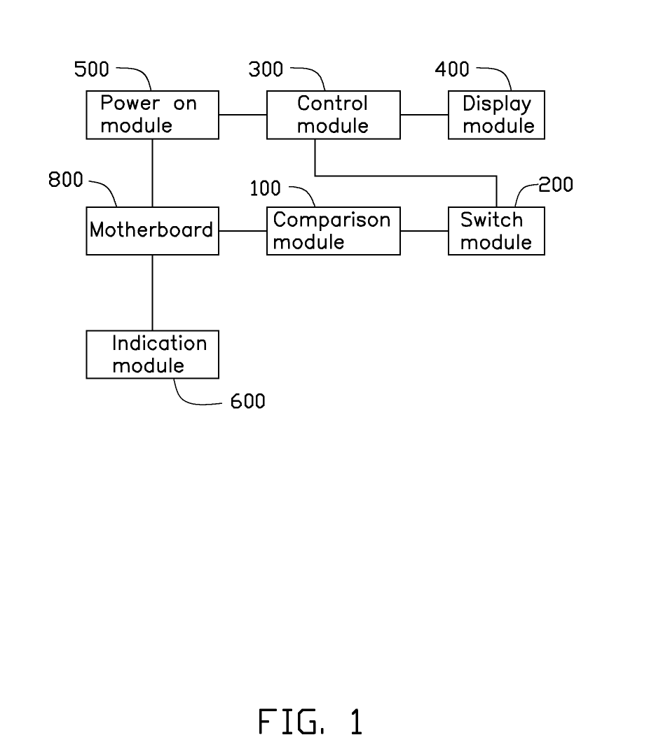

FIG. 1 is a block diagram of a discharge test circuit for testing whether there is any electric current remaining on a motherboard 800, in accordance with one embodiment. The discharge test circuit includes a comparison module 100, a switch module 200, a control module 300, a display module 400, a power on module 500, and an indication module 600. The comparison module 100 receives a first DC (direct current) voltage from the motherboard 800, and compares the first DC voltage with a reference voltage before outputting a switch signal. The switch module 200 receives the switch signal, and outputs a control signal accordingly. The control module 300 receives the control signal, and determines a status of the motherboard 800 before outputting a display signal. The display module 400 receives the display signal, and displays whether there is current remaining on the motherboard 800. The control module 300 outputs a power on signal. The power on module 500 receives the power on signal, and turns on the motherboard 800 accordingly. The motherboard 800 outputs an indication signal when the motherboard 800 is turned on successfully. The indication module 600 receives the indication signal, and indicates a status of the motherboard 800. The motherboard 800 includes a positive input terminal, a negative input terminal, a first indication signal output terminal PA1, and a second indication signal output terminal PA2. In other embodiments, any of various other kinds of circuit boards can be employed instead of the motherboard 800.

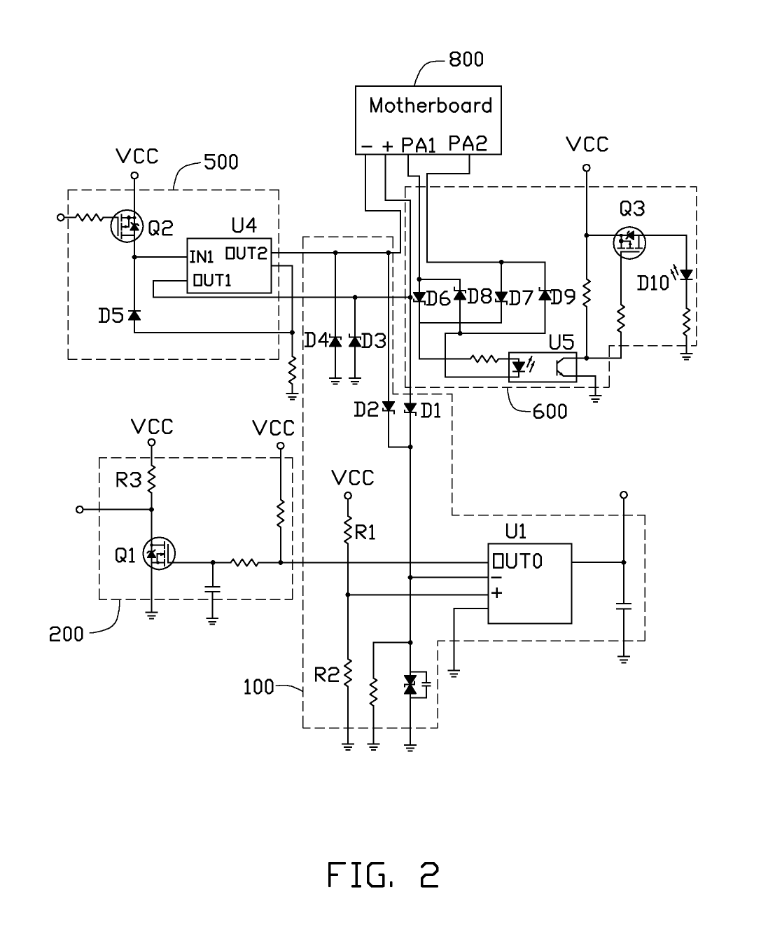

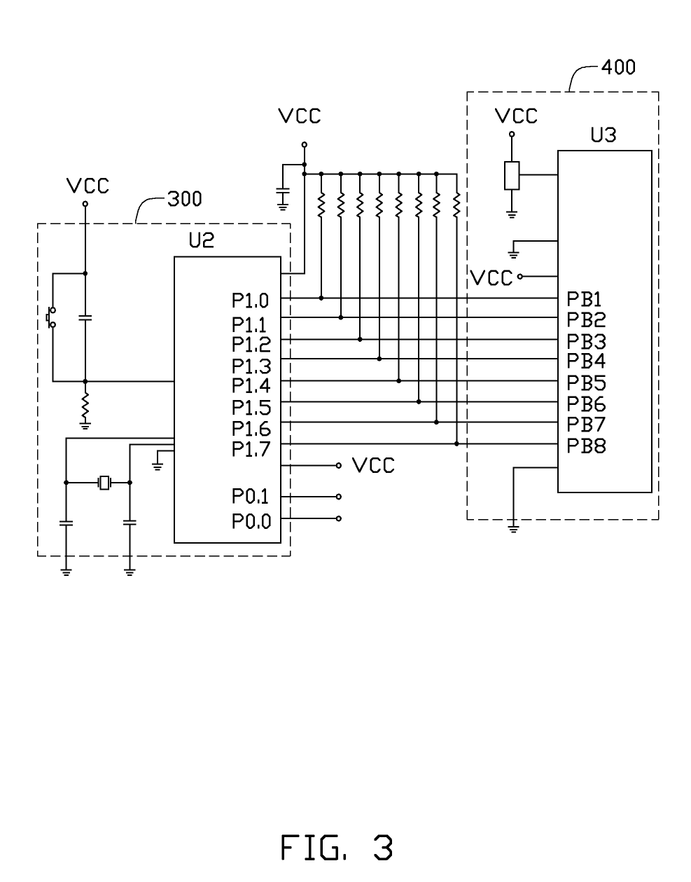

FIG. 2 is a circuit diagram of the comparison module 100, the switch module 200, the power on module 500, the indication module 600, and the motherboard 800 in accordance with one embodiment. FIG. 3 is a circuit diagram of the control module 300 and the display module 400 in accordance with one embodiment. The comparison module 100 includes a comparator U1, a first diode D1, a second diode D2, a third diode D3, a fourth diode D4, a first resistor R1, and a second resistor R2. The comparator U1 includes a non-inverting input terminal, an inverting input terminal, and an output terminal OUT0. Anodes of the first diode D1 and the second diode D2 are electrically connected to the positive input terminal and the negative input terminal of the motherboard 800, respectively. Cathodes of the first diode D1 and the second diode D2 are electrically connected to the inverting input terminal of the comparator U1. Cathodes of the third diode D3 and the fourth diode D4 are electrically connected to the positive input terminal and the negative input terminal of the motherboard 800, respectively. Anodes of the third diode D3 and the fourth diode D4 are grounded.

The non-inverting input terminal of the comparator U1 receives a second DC voltage (VCC in the drawings) via the first resistor R1. The second DC voltage VCC is obtained from the motherboard 800. The non-inverting input terminal of the comparator U1 is grounded via the second resistor R2. A connection point between the first resistor R1 and the second resistor R2 outputs the reference voltage to the non-inverting input terminal of the comparator U1. That is, the second DC voltage is divided by the first resistor R1 and the second resistor R2 to generate the reference voltage at the connection point. In one embodiment, a resistance of the first resistor R1 is 10 kiloohms. A resistance of the second resistor R2 is 910 ohms. A value of the second DC voltage is +5 volts.

The switch module 200 includes a first MOSFET (metal oxide semiconductor field effect transistor) Q1 and a third resistor R3. A gate of the first MOSFET Q1 is electrically connected to the output terminal OUT0 of the comparator U1 to receive the switch signal. A source of the first MOSFET Q1 is grounded. A drain of the first MOSFET Q1 receives the second DC voltage via the third resistor R3. The drain of the first MOSFET Q1 outputs the control signal. In one embodiment, the first MOSFET Q1 is an N-channel MOSFET.

The control module 300 includes a micro controller U2. The micro controller U2 includes a control signal input terminal P0.0, a control signal output terminal P0.1, and a plurality of display signal output terminals P1.0-P1.7. The control signal input terminal P0.0 is electrically connected to the drain of the first MOSFET Q1 to receive the control signal. The plurality of display signal output terminals P1.0-P1.7 output the display signal. The display module 400 includes a liquid crystal display (LCD) panel U3. The LCD panel U3 includes a plurality of display signal input terminals PB1-PB8. Each of the plurality of display signal input terminals PB1-PB8 is electrically connected to the corresponding display signal output terminal of P1.0-P1.7 to receive the display signal.

The power on module 500 includes a relay U4, a second MOSFET Q2, and a fifth diode D5. The relay U4 includes an input terminal IN1, a first output terminal OUT1, and a second output terminal OUT2. A gate of the second MOSFET Q2 is electrically connected to the control signal output terminal P0.1 to receive the power on signal. A source of the second MOSFET Q2 receives the second DC voltage. A drain of the second MOSFET Q2 is electrically connected to a cathode of the fifth diode D5.

An anode of the fifth diode D5 is grounded. The drain of the second MOSFET Q2 is electrically connected to the input terminal IN1 of the relay U4. The first output terminal OUT1 and the second output terminal OUT2 of the relay U4 are electrically connected to the positive input terminal and the negative input terminal of the motherboard 800, respectively. In one embodiment, the second MOSFET Q2 is a P-channel MOSFET.

The indication module 600 includes a photocoupler U5, a third MOSFET Q3, a sixth diode D6, a seventh diode D7, an eighth diode D8, a ninth diode D9, and an LED (light emitting diode) D10. The photocoupler U5 includes a light emitting unit and a switch unit. Anodes of the sixth diode D6 and the seventh diode D7 are electrically connected to the first indication signal output terminal PA1 and the second indication signal output terminal PA2 of the motherboard 800, respectively. Cathodes of the sixth diode D6 and the seventh diode D7 are electrically connected to an anode of the light emitting unit. Cathodes of the eighth diode D8 and the ninth diode D9 are electrically connected to the first indication signal output terminal PA1 and the second indication signal output terminal PA2 of the motherboard 800, respectively. Anodes of the eighth diode D8 and the ninth diode D9 are electrically connected to a cathode of the light emitting unit. A gate of the third MOSFET Q3 is grounded via the switch unit. A source of the third MOSFET Q3 receives the second DC voltage. A drain of the third MOSFET Q3 is electrically connected to an anode of the LED D10. A cathode of the LED D10 is grounded. In one embodiment, the third MOSFET Q3 is a P-channel MOSFET.

In operation, the control signal output terminal P0.1 of the micro controller U2 outputs a low voltage level power on signal to the gate of the second MOSFET Q2. Typically, such output is activated by software embedded in the motherboard 800. The second MOSFET Q2 turns on. The drain of the second MOSFET Q2 outputs a high voltage level (i.e. the second DC voltage) to the input terminal IN1 of the relay U4. The relay U4 is powered on to close the first output terminal OUT1 and the second output terminal OUT2. The positive input terminal and the negative input terminal of the motherboard 800 are closed to turn on the motherboard 800. The first indication signal output terminal PA1 of the motherboard 800 outputs a high voltage level indication signal. The second indication signal output terminal PA2 of the motherboard 800 outputs a low voltage level indication signal. The light emitting unit of the photocoupler U5 turns on and emits light. The switch unit of the photocoupler U5 receives light signals from the light emitting unit and turns on. The gate of the third MOSFET Q3 receives a low voltage level (i.e., ground) signal via the switch unit. The third MOSFET Q3 turns on. The drain of the third MOSFET Q3 outputs the high voltage level (i.e. the second DC voltage) to the anode of the LED D10. The LED D10 turns on and emits light to indicate that the motherboard 800 is turned on successfully.

After the motherboard 800 has been running for a predetermined period of time, the motherboard 800 turns off. Typically, this turning off operation is activated by software embedded in the motherboard 800. The inverting input terminal of the comparator U1 detects the first DC voltage on the positive input terminal of the motherboard 800. The comparator U1 compares the first DC voltage and the reference voltage. When there is a current remaining on the motherboard 800, the first DC voltage is greater than the reference voltage. In such case, the output terminal OUT0 of the comparator U1 outputs a low voltage level switch signal to the gate of the first MOSFET Q1. The first MOSFET Q1 turns off. The drain of the first MOSFET Q1 outputs a high voltage level control signal to the microcontroller U2. The plurality of display signal output terminals P1.0-P1.7 outputs the display signal indicating there is current on the motherboard 800 to the plurality of display signal input terminals PB1-PB8. The display module 400 thus indicates there is current remaining on the motherboard 800. The microcontroller U2 stops outputting the low voltage level power on signal, until the motherboard 800 has completely discharged (see below).

When the motherboard 800 has completely discharged, the first DC voltage is less than the reference voltage. In such case, the output terminal OUT0 of the comparator U1 outputs a high voltage level switch signal to the gate of the first MOSFET Q1. The first MOSFET Q1 turns on. The drain of the first MOSFET Q1 outputs a low voltage level (i.e., ground) control signal to the microcontroller U2. The plurality of display signal output terminals P1.0-P1.7 outputs the display signal indicating that the motherboard 800 has completely discharged to the plurality of display signal input terminals PB1-PB8. The display module 400 indicates complete discharge of the motherboard 800. The microcontroller U2 outputs the low voltage level power on signal again, to turn on the motherboard 800 once more.

Even though numerous characteristics and advantages of the present disclosure have been set forth in the foregoing description, together with details of the structures and functions of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A discharge test circuit for testing whether there is current on a circuit board, the discharge test circuit comprising:
a comparison module adapted to receive a first direct current (DC) voltage from the circuit board, compare the first DC voltage with a reference voltage, and output a switch signal according to a result of the comparison;
a switch module adapted to receive the switch signal, and output a control signal accordingly;
a control module adapted to receive the control signal, determine a status of the circuit board according to the control signal, and output a display signal corresponding to the status of the circuit board; and
a display module adapted to receive the display signal, and display whether there is current on the circuit board according to the display signal.

2. The discharge test circuit of claim 1, wherein the comparison module comprises a comparator; the comparator comprises a non-inverting input terminal, an inverting input terminal, and an output terminal; the non-inverting input terminal of the comparator receives the reference voltage; the inverting input terminal of the comparator is adapted to be electrically connected to a positive input terminal of the circuit board to receive the first DC voltage; and the output terminal of the comparator outputs the switch signal.

3. The discharge test circuit of claim 2, wherein the comparison module further comprises a first diode, a second diode, a third diode, and a fourth diode; anodes of the first diode and the second diode are adapted to be electrically connected to a positive input terminal and a negative input terminal of the circuit board, respectively; cathodes of the first diode and the second diode are electrically connected to the inverting input terminal of the comparator; cathodes of the third diode and the fourth diode are adapted to be electrically connected to the positive input terminal and the negative input terminal of the circuit board, respectively; and anodes of the third diode and the fourth diode are adapted to be grounded.

4. The discharge test circuit of claim 3, wherein the comparison module further comprises a first resistor and a second resistor; the non-inverting input terminal of the comparator receives a second DC voltage via the first resistor; and the non-inverting input terminal of the comparator is adapted to be grounded via the second resistor.

5. The discharge test circuit of claim 4, wherein the switch module comprises a first metal oxide semiconductor field effect transistor (MOSFET) and a third resistor; a gate of the first MOSFET is electrically connected to the output terminal of the comparator to receive the switch signal; a source of the first MOSFET is adapted to be grounded; a drain of the first MOSFET receives the second DC voltage via the third resistor; and the drain of the first MOSFET outputs the control signal.

6. The discharge test circuit of claim 5, wherein the control module comprises a micro controller; the micro controller comprises a control signal input terminal and a plurality of display signal output terminals; the control signal input terminal of the micro controller is electrically connected to the drain of the first MOSFET to receive the control signal; and the plurality of display signal output terminals of the micro controller output the display signal.

7. The discharge test circuit of claim 6, wherein the display module comprises a plurality of display signal input terminals; and the plurality of display signal input terminals are electrically connected to the plurality of display signal output terminals to receive the display signal.

8. The discharge test circuit of claim 7, further comprising a power on module; the power on module comprises a relay, a second MOSFET, and a fifth diode; the relay comprises an input terminal, a first output terminal, and a second output terminal; the micro controller further comprises a control signal output terminal; a gate of the second MOSFET is electrically connected to the control signal output terminal to receive the power on signal; a source of the second MOSFET receives the second DC voltage; a drain of the second MOSFET is electrically connected to a cathode of the fifth diode; an anode of the fifth diode is adapted to be grounded; the drain of the second MOSFET is electrically connected to the input terminal of the relay; and the first output terminal and the second output terminal are adapted to be electrically connected to the positive input terminal and the negative input terminal of the circuit board, respectively.

9. The discharge test circuit of claim 8, further comprising an indication module; wherein the indication module comprises a photocoupler, a third MOSFET, and a light emitting diode (LED); the photocoupler comprises a light emitting unit and a switch unit; an anode of the light emitting unit is adapted to be electrically connected to a first indication signal output terminal of the circuit board; a cathode of the light emitting unit is adapted to be electrically connected to a second indication signal output terminal of the circuit board; a gate of the third MOSFET is adapted to be grounded via the switch unit; a source of the third MOSFET receives the second DC voltage; a drain of the third MOSFET is electrically connected to an anode of the LED; and a cathode of the LED is adapted to be grounded.

10. The discharge test circuit of claim 9, wherein the indication module further comprises a sixth diode, a seventh diode, an eighth diode, and a ninth diode; anodes of the sixth diode and the seventh diode are adapted to be electrically connected to the first indication signal output terminal and the second indication signal output terminal of the circuit board, respectively; cathodes of the sixth diode and the seventh diode are electrically connected to an anode of the light emitting unit; cathodes of the eighth diode and the ninth diode are adapted to be electrically connected to the first indication signal output terminal and the second indication signal output terminal of the circuit board, respectively; and anodes of the eighth diode and the ninth diode are electrically connected to a cathode of the light emitting unit.

11. A discharge test circuit comprising:
a circuit board adapted to output a first direct current (DC) voltage;
a comparison module adapted to receive the first DC voltage, compare the first DC voltage with a reference voltage, and output a switch signal according to a result of the comparison;
a switch module adapted to receive the switch signal, and output a control signal accordingly;
a control module adapted to receive the control signal, determine a status of the circuit board according to the control signal, and output a display signal corresponding to the status of the circuit board; and
a display module adapted to receive the display signal, and display whether there is current on the circuit board according to the display signal.

12. The discharge test circuit of claim 11, wherein the circuit board comprises a positive input terminal; the comparison module comprises a comparator; the comparator comprises a non-inverting input terminal, an inverting input terminal, and an output terminal; the non-inverting input terminal of the comparator receives the reference voltage; the inverting input terminal of the comparator is electrically connected to the positive input terminal of the circuit board to receive the first DC voltage; and the output terminal of the comparator outputs the switch signal.

13. The discharge test circuit of claim 12, wherein the circuit board further comprises a negative input terminal; the comparison module further comprises a first diode, a second diode, a third diode, and a fourth diode; anodes of the first diode and the second diode are electrically connected to the positive input terminal and the negative input terminal of the circuit board, respectively; cathodes of the first diode and the second diode are electrically connected to the inverting input terminal of the comparator; cathodes of the third diode and the fourth diode are electrically connected to the positive input terminal and the negative input terminal of the circuit board, respectively; and anodes of the third diode and the fourth diode are adapted to be grounded.

14. The discharge test circuit of claim 13, wherein the comparison module further comprises a first resistor and a second resistor; the non-inverting input terminal of the comparator receives a second DC voltage via the first resistor; and the non-inverting input terminal of the comparator is adapted to be grounded via the second resistor.

15. The discharge test circuit of claim 14, wherein the switch module comprises a first metal oxide semiconductor field effect transistor (MOSFET) and a third resistor; a gate of the first MOSFET is electrically connected to the output terminal of the comparator to receive the switch signal; a source of the first MOSFET is adapted to be grounded; a drain of the first MOSFET receives the second DC voltage via the third resistor; and the drain of the first MOSFET outputs the control signal.

16. The discharge test circuit of claim 15, wherein the control module comprises a micro controller; the micro controller comprises a control signal input terminal and a plurality of display signal output terminals; the control signal input terminal of the micro controller is electrically connected to the drain of the first MOSFET to receive the control signal; and the plurality of display signal output terminals of the micro controller output the display signal.

17. The discharge test circuit of claim 16, wherein the display module comprises a plurality of display signal input terminals; and the plurality of display signal input terminals are electrically connected to the plurality of display signal output terminals to receive the display signal.

18. The discharge test circuit of claim 17, further comprising a power on module; the power on module comprises a relay, a second MOSFET, and a fifth diode ; the relay comprises an input terminal, a first output terminal, and a second output terminal; the micro controller further comprises a control signal output terminal; a gate of the second MOSFET is electrically connected to the control signal output terminal to receive the power on signal; a source of the second MOSFET receives the second DC voltage; a drain of the second MOSFET is electrically connected to a cathode of the fifth diode; an anode of the fifth diode is adapted to be grounded; the drain of the second MOSFET is electrically connected to the input terminal of the relay; and the first output terminal and the second output terminal are electrically connected to the positive input terminal and the negative input terminal of the circuit board, respectively.

19. The discharge test circuit of claim 18, further comprising an indication module; the indication module comprises a photocoupler, a third MOSFET, and a light emitting diode (LED); the photocoupler comprises a light emitting unit and a switch unit; the circuit board further comprises a first indication signal output terminal and a second indication signal output terminal; the first indication signal output terminal is electrically connected to an anode of the light emitting unit; the second indication signal output terminal is electrically connected to a cathode of the light emitting unit; a gate of the third MOSFET is adapted to be grounded via the switch unit; a source of the third MOSFET receives the second DC voltage; a drain of the third MOSFET is electrically connected to an anode of the LED; and a cathode of the LED is adapted to be grounded.

20. The discharge test circuit of claim 19, wherein the indication module further comprises a sixth diode, a seventh diode, an eighth diode, and a ninth diode; anodes of the sixth diode and the seventh diode are electrically connected to the first indication signal output terminal and the second indication signal output terminal of the circuit board, respectively; cathodes of the sixth diode and the seventh diode are electrically connected to an anode of the light emitting unit; cathodes of the eighth diode and the ninth diode are electrically connected to the first indication signal output terminal and the second indication signal output terminal of the circuit board, respectively; and anodes of the eighth diode and the ninth diode are electrically connected to a cathode of the light emitting unit.
